(19) United States
(12) Patent Application Publication
(10) Pub. No.: US 2026/0245651 A1
(43) Pub. Date: Aug. 20, 2026

(54) STORAGE DEVICE, OPERATING METHOD OF THE SAME, AND OPERATING METHOD OF ELECTRONIC SYSTEM INCLUDING THE SAME

(71) Applicant: SK hynix Inc., Gyeonggi-do (KR)

(72) Inventors: Jae Gwan KIM, Gyeonggi-do (KR); Bu Yong SONG, Gyeonggi-do (KR)

(21) Appl. No.: 19/308,350

(22) Filed: Aug. 25, 2025

(30) Foreign Application Priority Data
Feb. 20, 2025 (KR) 10-2025-0022395
Mar. 28, 2025 (KR) 10-2025-0040423

(51) Int. Cl. G11C 29/00; G11C 16/26; G11C 16/34

(52) U.S. Cl. CPC G11C 29/76; G11C 16/26; G11C 16/3459; G11C 16/3495

(57) ABSTRACT

According to an embodiment of the present disclosure, a storage device is provided. The storage device includes a memory device having a plurality of memory blocks, and configured to perform a first program operation and a second program operation on a first memory block among the plurality of memory blocks to copy data from a second memory block into the first memory block, and a controller configured to control the memory device to select a third memory block among the plurality of memory blocks in response to a program failure that occurs in the first memory block, and to write a dummy bit to a second region of the third memory block corresponding to a first region of the first memory block, wherein the first region stores a first portion of the data for which the first program operation and the second program operation are completed.

### CROSS-REFERENCE TO RELATED APPLICATION

The present application claims priority under 35 U.S.C. § 119(a) to Korean patent application number 10-2025-0022395 filed on Feb. 20, 2025 and Korean patent application number 10-2025-0040423 filed on Mar. 28, 2025, the entire disclosures of which are incorporated by reference herein.

### BACKGROUND

### 1. Technical Field

Various embodiments of the present disclosure relate to a storage device, an operating method of the same, and an operating method of electronic system including the same, and more particularly to, a storage device of performing program operations of memory blocks, a method of operating the storage device, and a method of operating an electronic system including the storage device.

### 2. Related Art

A memory device stores data in response to a write request and outputs the stored data in response to a read request. For example, memory devices are divided into volatile memory devices, such as dynamic random access memory (DRAM), static RAM (SRAM), and the like, which lose the stored data when the power supply is cut off, and non-volatile memory devices, such as flash memory devices, phase-change RAM (PRAM), magnetic RAM (MRAM), resistive RAM (RRAM), and the like, which retain data even when the power supply is cut off.

In general, non-volatile memory devices can store data based on random (or arbitrary) access. Random access can reduce the lifetime of the storage device as frequent garbage collection (GC) is performed over the entire area. To avoid this, data can be moved from memory blocks in non-volatile memory devices. In the event of a program failure, significant overhead can be incurred to move data to replacement memory blocks. This overhead can degrade the performance of the storage device, and thus, methods to reduce the overhead may be required.

### SUMMARY

Embodiments of the present disclosure provide a storage device performing a program operation, a method of operating the storage device, and a method of operating an electronic system including the storage device.

According to an embodiment of the present disclosure, a storage device may include a memory device including a plurality of memory blocks, and configured to perform a first program operation and a second program operation on a first memory block among the plurality of memory blocks to copy data from a second memory block into the first memory block, and a controller configured to control the memory device to select a third memory block among the plurality of memory blocks in response to a program failure that occurs in the first memory block, and to write a dummy bit to a second region of the third memory block corresponding to a first region of the first memory block, wherein the first region stores a first portion of the data for which the first program operation and the second program operation are completed.

According to an embodiment of the present disclosure, a method of operating a storage device including a controller and a memory device may include performing, by the memory device, a first program operation and a second program operation on a first memory block to copy data from a second memory block into the first memory block, selecting, by the controller, a third memory block in response to a program failure that occurs in the first memory block, and writing, by the memory device, a dummy bit to a second region of the third memory block corresponding to a first region of the first memory block, wherein the first region stores a first portion of the data for which the first program operation and the second program operation are completed.

According to an embodiment of the present disclosure, a method of operating an electronic system including a host device, a controller and a memory device may include performing, by the memory device, a first program operation and a second program operation on a first memory block to copy data from a second memory block into the first memory block, selecting, by the controller, a third memory block in response to a program failure occurs that in the first memory block, writing, by the memory device, a dummy bit to a second region of the third memory block corresponding to a first region of the first memory block, wherein the first region stores a first portion of the data for which the first program operation and the second program operation are completed, transferring, by the host device, a read request for the first portion to the controller, providing, by the controller, the memory device with a first command for a read operation of the first portion and a first address indicating the second region in response to the read request, reading, by the memory device, the dummy bit from the second region indicated by the first address in response to the first command, providing, by the memory device, a read fail signal to the controller based on reading the dummy bit, providing, by the controller, the memory device with a second command for the read operation of the first portion and a second address indicating the first region in response to the read fail signal, providing, by the memory device, the first portion stored in the first region indicated by the second address to the controller based on the second command, and transferring, by the controller, the first portion to the host device.

### BRIEF DESCRIPTION OF THE DRAWINGS

FIG. 1 is a block diagram of an electronic system according to an embodiment of the present disclosure;

FIG. 2 is a diagram illustrating the structure of a memory block according to some embodiments of the present disclosure;

FIG. 3 is a block diagram of a storage device according to an embodiment of the present disclosure;

FIG. 4 is a diagram illustrating a storage device according to some embodiments of the present disclosure;

FIG. 5 is a diagram illustrating first and second program operations;

FIG. 6A is a diagram illustrating a copy operation of a memory block according to some embodiments of the present disclosure;

FIG. 6B is a diagram illustrating a copy operation of a memory block according to some embodiments of the present disclosure;

FIG. 7 is a diagram illustrating a read operation of a storage device according to some embodiments of the present disclosure;

FIG. 8 is a flowchart illustrating a method of operating a storage device according to an embodiment of the present disclosure;

FIG. 9 is a flowchart illustrating a method of operating a storage device according to some embodiments of the present disclosure;

FIG. 10 is a block diagram illustrating an electronic system according to some embodiments of the present disclosure;

FIG. 11 is a diagram illustrating an electronic system according to some embodiments of the present disclosure;

FIG. 12 is a diagram illustrating an electronic system according to some embodiments of the present disclosure; and

FIG. 13 is a block diagram of a network system including an electronic system according to some embodiments of the present disclosure.

### DETAILED DESCRIPTION

Specific structural or functional descriptions of the embodiments in accordance with concepts which are disclosed in this specification are illustrated only to describe the embodiments in accordance with the concepts and the embodiments in accordance with the concepts may be carried out by various forms but the descriptions are not limited to the embodiments described in this specification.

While terms such as “first” and “second” may be used to describe various components, such components must not be understood as being limited to the above terms. The above terminologies are used to distinguish one component from the other component. In addition, the singular forms are intended to include the plural forms as well, unless the context clearly indicates otherwise.

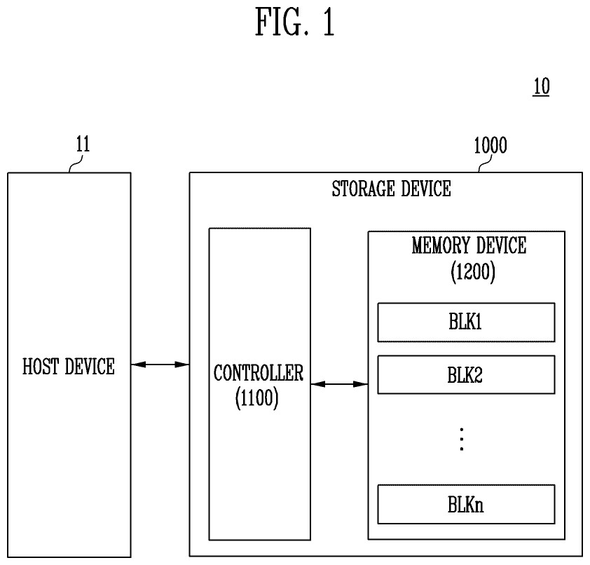

FIG. 1 is a block diagram of an electronic system 10 according to an embodiment of the present disclosure. Referring to FIG. 1, the electronic system 10 may be a computing system configured to process various kinds of information and/or store the processed information as data. In some embodiments, the electronic system 10 may be a personal computer (PC), a notebook, a laptop, a server, a workstation, a tablet PC, a smartphone, a digital camera, or a black box, or the like.

The electronic system 10 may include a host device 11 and a storage device 1000. The host device 11 may control various operations of the electronic system 10. More specifically, the host device 11 may control the operations of other components including the electronic system 10. The host device 11 may be a general purpose processor, a dedicated processor, an application processor (AP), or the like.

The host device 11 may communicate with the storage device 1000. For example, the host device 11 may request a program operation, a read operation, an erase operation, or the like from the storage device 1000. The host device 11 may transfer a host request, data, and a logical address for a program operation of the storage device 1000 to the storage device 1000. The host device 11 may transfer a host request and a logical address for a read operation of the storage device 1000 to the storage device 1000.

The storage device 1000 may store data. For example, the host device 11 may control the storage device 100 to store data. In some embodiments, the storage device 1000 may include at least one of a solid state device (SSD), an embedded memory, and a removable external memory. When the storage device 1000 is an SSD, the storage device 1000 may conform to the non-volatile memory express (NVMe) standard. When the storage device 1000 is an embedded memory or a removable external memory, the storage device 1000 may conform to the Universal Flash Storage (UFS) or embedded Multi-Media Card (eMMC) standards. The host device 11 and the storage device 1000 may each generate packets based on a standard protocol employed and may transfer the generated packets to each other.

The storage device 1000 may include a controller 1100 and the memory device 1200. The controller 1100 may control the operations of the storage device 1000. For example, the controller 1100 may control the operations of the storage device 1000 in accordance with an internal policy or in response to a request from the host device 11. The controller 1100 may store data in the memory device 1200, or read data stored in the memory device 1200 in accordance with an internal policy or in response to a request from the host device 11.

The controller 1100 may, in response to a host request corresponding to a program operation received from the host device 11, generate a program command and provide the generated program command to the memory device 1200. The controller 1100 may, in response to a host request corresponding to a read operation received from the host device 11, generate a command and provide the generated command to the memory device 1200. The controller 1100 may transfer the read data from the memory device 1200 to the host device 11.

The controller 1100 may control the memory device 1200 to store data. The memory device 1200 may include a plurality of memory blocks BLK1 to BLKn. Each of the plurality of memory blocks BLK1 to BLKn may include a plurality of memory cells, and the plurality of memory cells may constitute a plurality of strings or a plurality of pages. In some embodiments, a page may be a unit for storing data in the memory device 1200 or for reading data stored in the memory device 1200. A memory block may be a unit for erasing data stored in the memory device 1200.

The memory device 1200 may move or copy data within the memory device 1200 to perform various functions. For example, the memory device 1200 may move or copy data from a first memory block to a second memory block to perform at least one of a garbage collection operation, a read reclaim operation, a read refresh operation, a wear leveling operation, and an over-provision operation.

While the memory device 1200 is performing an operation to move or copy data from a source memory block to a destination memory block, a program failure may occur on the destination memory block, which therefore becomes a program-failed memory block. A general memory device may cope with the program failure on the destination memory block by moving or copying the whole data from the source memory block to a replacement memory block. Within the whole data to be moved or copied into the destination memory block, i.e., the program-failed memory block, a part of the whole data may be program-completed (i.e., normally programmed into the program-failed memory block) and the remaining part of the whole data may be program-incomplete (i.e., not normally programmed into the program-failed memory block) when the program failure occurs on the destination memory block. The operation of moving or copying the whole data back to the replacement memory block may require a large overhead. The general memory device may not be able to receive a host request from a general host device until the moving or copying the whole data back to the replacement memory block is completed or may require a long time to perform the host request. Accordingly, in the event of the program failure on the program-failed memory block, the general memory device may suffer from a long latency caused by the moving or copying the whole data back to the replacement memory block, and this long latency may degrade the performance of the storage device.

The memory device 1200 according to an embodiment of the present disclosure may write a dummy bit into a dummy region within the replacement memory block, the dummy region corresponding to a program-completed region within the failed memory block. The program-completed region may be a region on which program operations have been completed upon the program failure within the failed memory block. That is, the program-completed region within the failed memory block may store therein the program-completed part of whole data upon the program failure on the program-failed memory block. When the program failure occurs on the destination memory block during an operation of moving or copying the whole data from the source memory block to the destination memory block, the memory device 1200 may reduce overhead by programming a dummy bit into the dummy region corresponding to the program-completed region while programming, into a region other than the dummy region within the replacement memory block, the program-incomplete part of whole data from the source memory block. Thus, the memory device 1200 may improve the performance of the storage device. A more detailed description thereof will be provided below.

The memory device 1200 may be a NAND flash memory, but the embodiments of the present disclosure are not limited thereto. The memory device 1200 may be one of a variety of storage devices which may retain the stored data even when the power supply is cut off, such as phase-change random access memory (PRAM), magnetic random access memory (MRAM), resistive random access memory (RRAM), ferroelectric random access memory (FRAM), and the like.

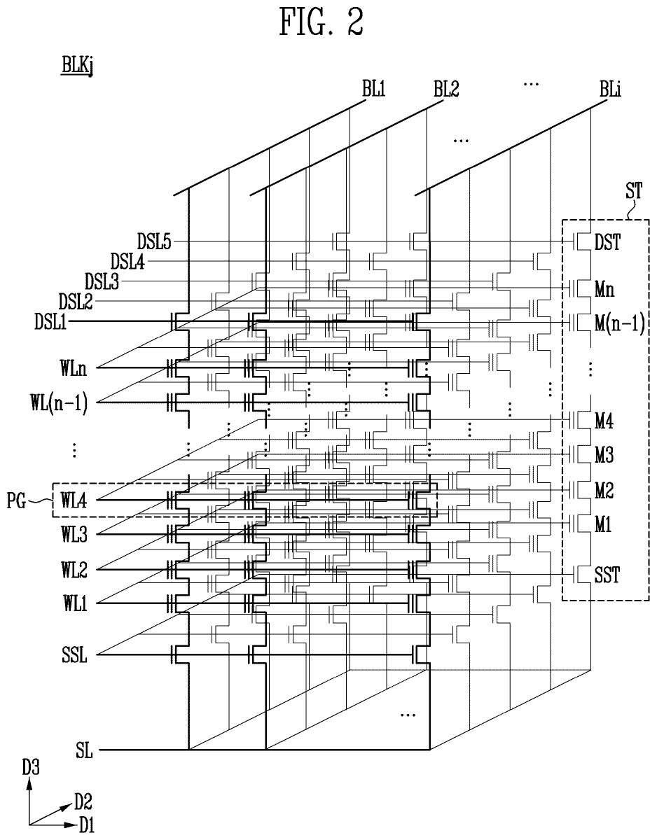

FIG. 2 is a diagram illustrating the structure of a memory block BLKj according to some embodiments of the present disclosure. Referring to FIG. 2, a structure of the jth memory block BLKj of the plurality of memory blocks BLK1 to BLKn of FIG. 1 is shown, where j is any positive integer between 1 and n.

Since the plurality of memory blocks BLK1 to BLKn are configured identically to each other, the jth memory block BLKj is shown as an example. The jth memory block BLKj may include a source line SL and strings ST coupled between first to ith bit lines BL1 to BLi. The strings ST may be coupled in common to the source line SL, coupled in common to each of the first to ith bit lines BL1 to BLi, and coupled to different first to ith bit lines BL1 to BLi, respectively. The strings ST may be arranged spaced apart from each other along a first direction D1 and a second direction D2, and may extend along a third direction D3. The first to ith bit lines BL1 to BLi may be arranged spaced apart from each other along the first direction D1, and each of the first to ith bit lines BL1 to BLi may extend along the second direction D2.

The numbers of source select transistors SST, first to nth memory cells M1 to Mn, and drain select transistors DST included in each of the strings ST may vary depending on the memory device. For example, while one source select transistor SST and one drain select transistor DST are shown included in each of the strings ST, a plurality of source select transistors SST and a plurality of drain select transistors DST may be included.

Gates of the source select transistors SST included in different strings ST may be coupled to source select lines SSL, gates of the first to nth memory cells M1 to Mn may be coupled to first to nth word lines WL1 to WLn, and gates of the drain select transistors DST may be coupled to the first to fifth drain select lines DSL1 to DSL5, where n is a positive integer. The number of drain select lines is only illustrative, and the embodiments of the present disclosure are not limited thereto.

The source select lines SSL may be coupled in common to the source select transistors SST arranged along the first direction D1 and the second direction D2, but some of the source select lines SSL arranged along the second direction D2 may be spaced apart from each other. Each of the first to nth word lines WL1 to WLn may be coupled in common to memory cells arranged along the first direction D1 and the second direction D2. For example, the nth memory cells Mn arranged along the first direction D1 and the second direction D2 may be coupled in common to the nth word line WLn, and the nth word lines WLn may be coupled to each other. For example, (n−1)th memory cells M(n−1) arranged along the first direction D1 and the second direction D2 may be coupled in common to (n−1)th word lines WL(n−1), and the (n−1)th word lines WL(n−1) may be coupled to each other. The nth word line WLn and the (n−1)th word line WL(n−1) may be spaced apart from each other. A group of memory cells commonly coupled to one of the first to nth word lines WL1 to WLn may be a page PG. For example, fourth memory cells M4 coupled in common to a fourth word line WL4 may be one page PG. A program operation may be performed on units of the page PG. When the fourth word line WL4 is a selected word line, the remaining word lines may be non-selected word lines. The jth memory block BLKk may include pages PG equal to the number of first to nth word lines WL1 to WLn.

In some embodiments, a single memory cell may store one bit of data. A memory cell capable of storing one bit of data is typically referred to as a single level cell (SLC). One page PG may store one logical page LPG of data. One logical page LPG of data may include as many data bits as there are memory cells in the one page PG.

In some embodiments, a single memory cell may store two or more bits of data. Memory cells which may store two or more bits of data are typically referred to as multi-level cells (MLC). One physical page PG may store two or more logical pages of data.

In some embodiments, a single memory cell may store two or more bits of data. Memory cells which may store two or more bits of data are commonly referred to as triple level cells (TLC). One physical page PG may store three or more logical pages of data.

In some embodiments, a single memory cell may store four or more bits of data. Memory cells which may store four or more bits of data are typically referred to as quadruple level cells (QLC). One physical page PG may store four or more logical pages of data.

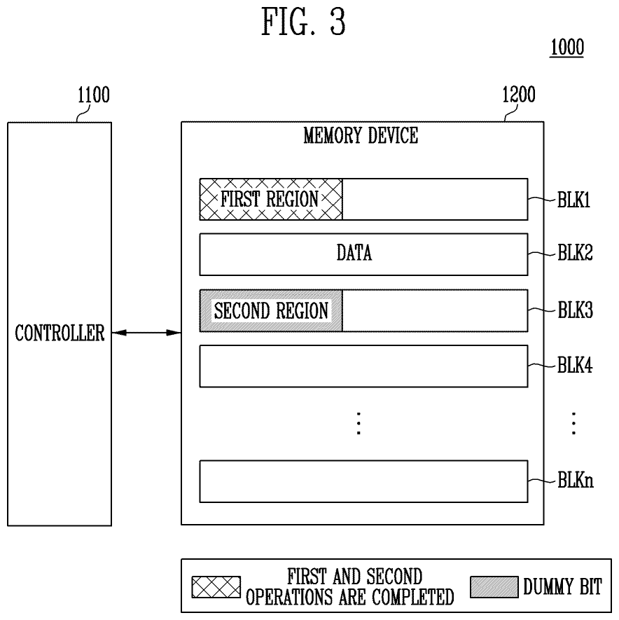

FIG. 3 is a block diagram of the storage device 1000 according to an embodiment of the present disclosure. Referring to FIG. 3, the storage device 1000 may include the controller 1100 and the memory device 1200. The controller 1100 may control various operations of the memory device 1200. For example, the controller 1100 may provide commands and addresses to the memory device 1200 to control various operations of the memory device 1200.

The controller 1100 may provide the memory device 1200 with a command, an address, and data for a write operation to the memory device 1200 to store data in the memory device 1200. To read data stored in the memory device 1200, the controller 1100 may provide the memory device 1200 with a command and an address for a read operation and may receive data from the memory device 1200.

The controller 1100 may control the memory device 1200 to move or copy data from one memory block of the memory device 1200 to another memory block. For example, the controller 1100 may control the memory device 1200 to move or copy data from a second memory block BLK2 to a first memory block BLK1.

The controller 1100 may control the memory device 1200 to move or copy data to a replacement memory block in response to determining that a program failure has occurred within the memory device 1200. For example, the controller 1100 may move or copy the data from the second memory block BLK2 to a third memory block BLK3 in response to determining that the program failure has occurred in the first memory block BLK1.

A program failure may occur on the first memory block BLK1 during a program operation of programming target data from the second memory block BLK2 into the first memory block BLK1. When the program failure occurs on the first memory block BLK1, the memory device 1200 has completed a program operation of programming a program-completed part of the whole target data into a first region within the first memory block BLK1 but has failed a program operation of programming a program-incomplete part of the whole target data into a region other than the first region within the first memory block BLK1. In response to determining that the program failure has occurred, the controller 1100 may write a dummy bit to a second region of the third memory block BLK3 corresponding to the first region. The first region and the second region may be physical regions where data is stored in the plurality of memory blocks BLK1 to BLKn.

The controller 1100 may reduce overhead during program failures within the memory device 1000 by controlling the memory device 1200 to move or copy only the program-incomplete data for which program operations have not been completed to a replacement memory block (e.g., the third memory block BLK3) when the program failure occurs, and to write a dummy bit to a region (e.g., the second region) corresponding to the program-completed data for which the program operations have already been completed.

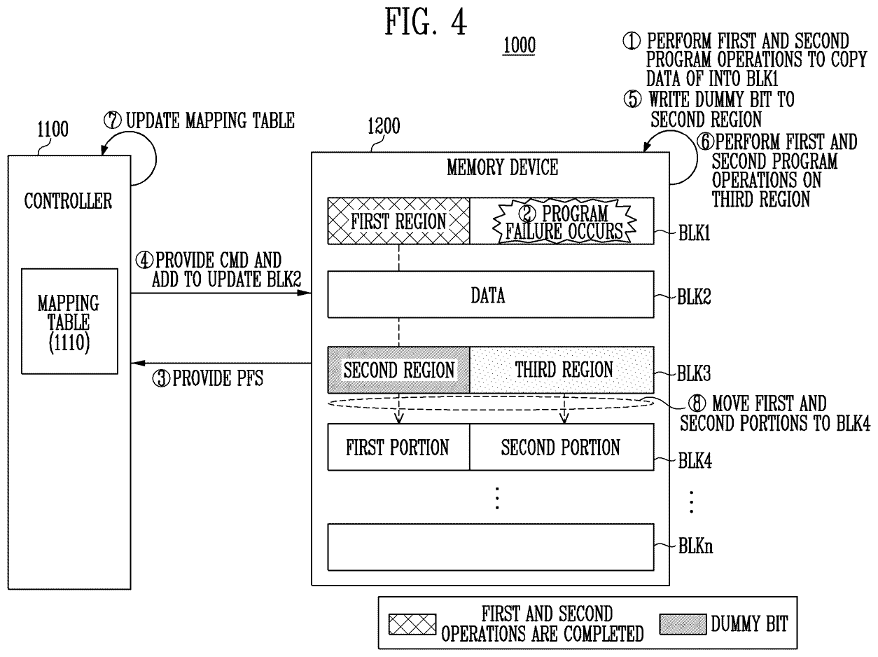

A more detailed description of the controller 1100 will be described below with reference to FIG. 4.

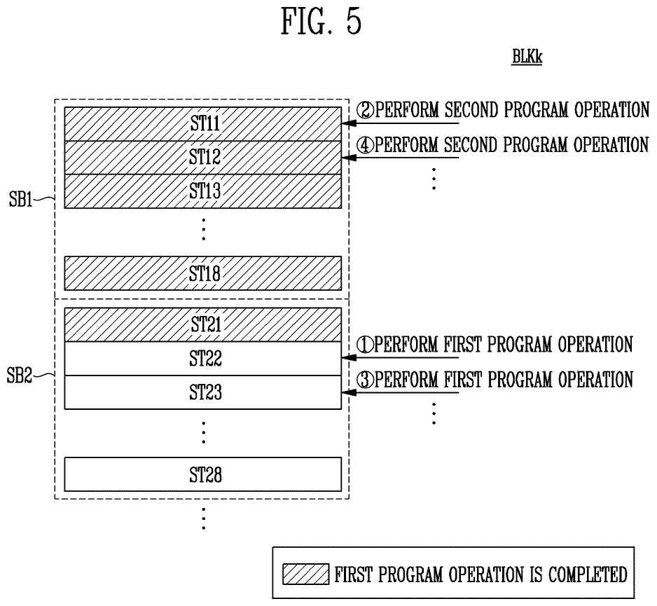

The memory device 1200 may include the plurality of memory blocks BLK1 to BLKn. At least some of the plurality of memory blocks BLK1 to BLKn may store data. The memory device 1200 may use various techniques to store the data in the plurality of memory blocks BLK1 to BLKn. For example, the memory device 1200 may perform one-shot program operations or foggy-fine program operations to store data in the plurality of memory blocks BLK1 to BLKn. Hereinafter, foggy-fine program operations are described, but the embodiments of the present disclosure are not limited thereto. A more detailed description of the foggy-fine program operations will be described below with reference to FIG. 5.

The memory device 1200 may perform foggy-fine program operations to store data in the plurality of memory blocks BLK1 to BLKn. For example, the memory device 1200 may perform a first program operation (e.g., a foggy-fine program operation) and a second program operation (e.g., a fine program operation) on the first memory block BLK1 to store data in the first memory block BLK1. The memory device 1200 may need to perform both the first program operation and the second program operation to write the data to the memory cell.

In some embodiments, the memory device 1200 may perform various functions, such as garbage collection operations, read reclaim operations, read refresh operations, wear leveling operations, and over-provision operations, to extend the endurance life of the memory device 1200 and/or increase storage space efficiency. The memory device 1200 may perform operations to move or copy data from one memory block (e.g., the second memory block BLK2) to another memory block (e.g., the first memory block BLK1) to perform various functions. The memory device 1200 may perform a first program operation (e.g., a foggy-fine program operation) and a second program operation (e.g., a fine program operation) on another memory block (e.g., the first memory block BLK1) to perform the move or copy operations.

While the memory device 1200 performs operations of moving or copying data from one memory block (e.g., the second memory block BLK2) to another memory block (e.g., the first memory block BLK1), a program failure may occur within another memory block (e.g., the first memory block BLK1). For example, while the memory device 1200 is performing a first program operation and a second program operation in the first memory block BLK1, a program failure may occur. When the program failure occurs, both the first program operation and the second program operation for the first region may have been completed.

The memory device 1200 may write a dummy bit to a region (e.g., the second region) of a replacement memory block (e.g., the third memory block BLK3) corresponding to the region (e.g., the first region) in which the first program operation and the second program operation are completed (e.g., the first region). For example, the controller 1100 may control the memory device 1200 to write a dummy bit to the second region (instead of a first portion of the data in the second memory block BLK2 for which both the first program operation and the second program operation have been completed). By writing the dummy bit (instead of performing both the first program operation and the second program operation of the first portion in the second region), the overhead in the event of the program failure may be reduced.

A more detailed description of the memory device 1200 will be described below with reference to FIG. 4.

FIG. 4 is a diagram illustrating the storage device 1000 according to some embodiments of the present disclosure. Referring to FIG. 4, the storage device 1000 may include the controller 1100 and the memory device 1200. The storage device 1000 is similar in some respects to the storage device 1000 of FIG. 3, and therefore, a duplicate description thereof will be omitted herein.

The controller 1100 may include a mapping table 1110. The controller 1100 may store a correspondence relationship between a logical address and a physical address where data is stored in the mapping table 1110. For example, the controller 1100 may store a correspondence relationship between a logical address and a physical address which indicates a location of data in the mapping table 1110. For example, when data stored in the second memory block BLK2 is moved to the first memory block BLK1, the controller 1100 may update the mapping table 1110 so that the physical address of the data may indicate the first memory block BLK1.

During a first step \textcircled{1}, the memory device 1200 may perform program operations on the first memory block BLK1. For example, the memory device 1200 may perform a first program operation (e.g., a foggy program operation) and a second program operation (e.g., a fine program operation) on the first memory block BLK1 to move or copy data from the second memory block BLK2 to the first memory block BLK1. In some embodiments, the controller 1100 may update the mapping table 1110 with information about the data from the second memory block BLK2 being moved or copied into the first memory block BLK1.

During a second step \textcircled{2}, a program failure may occur. For example, while the memory device 1200 is performing the first program operation and the second program operation within the first memory block BLK1, a program failure may occur. The program failure may indicate a failure of the first program operation or a failure of the second program operation. When a program failure occurs within the first memory block BLK1, both the first program operation and the second program operation may have been completed for some region (e.g., the first region) of the first memory block BLK1. The move or copy operation of the first portion of the data of the second memory block BLK2 (which may include a plurality of portions) may be completed for the first region of the first memory block BLK1.

During a third step \textcircled{3}, the memory device 1200 may provide a program fail signal PFS to the controller 1100. For example, the memory device 1200 may provide the program fail signal PFS to the controller 1100 in response to the program failure occurring within the first memory block BLK1.

During a fourth step \textcircled{4}, the controller 1100 may provide a command CMD and an address ADD to the memory device 1200 to move or copy data of the second memory block BLK2. For example, the controller 1100 may provide the command CMD and the address ADD to the memory device 1200 to write a dummy bit to a second region of the third memory block BLK3 corresponding to the first region storing a first portion of the data of the second memory block BLK2 for which the first program operation and the second program operation have been completed within the first memory block BLK1, and to write a second portion, which is the remaining portion of the data, to a third region of the third memory block BLK3.

In some embodiments, the controller 1100 may receive the program fail signal PFS from the memory device 1200 and select the third memory block BLK3 of the plurality of memory blocks BLK1 to BLKn to copy the data in the second memory block BLK2. For example, the controller 1100 may select the third memory block BLK3 to move or copy the second portion of the data within the first memory block BLK1 for which the first program operation and the second program operation have not been completed. To move or copy the second portion of the data to the third memory block BLK3, the controller 1100 may provide the memory device 1200 with the address ADD and the command indicating the third memory block.

During a fifth step \textcircled{5}, the memory device 1200 may write a dummy bit to the second region. For example, the memory device 1200 may receive the command CMD and the address ADD from the controller 1100, and may write the dummy bit to the second region of the third memory block BLK3 in response to the received command CMD and address ADD. The second region may correspond to the first region within the first memory block BLK1 which stores the first portion of the data for which the first program operation and the second program operation have been completed. The memory device 1200 may require a shorter time to write the dummy bit to the second region than the time to write the first portion of the data which requires completion of both the first program operation and the second program operation.

During a sixth step \textcircled{6}, the memory device 1200 may perform the first program operation and the second program operation in a third region of the third memory block BLK3. For example, the memory device 1200 may perform the first program operation and the second program operation on the third region of the third memory block BLK3 to move or copy the second portion which is the remaining portion of the data for which both the first program operation and the second program operation have not been completed within the first memory block BLK1 or in which the program failure has occurred.

During a seventh step \textcircled{7}, the controller 1100 may update the mapping table 1110. For example, the controller 1100 may update the information about the data in the second memory block BLK2 being moved or copied to the third memory block BLK3. In addition to storing information about the data from the second memory block BLK2 being stored in the third memory block BLK3, the mapping table 1110 may also store the information about the data (or a portion of the data) from the second memory block BLK2 being stored in the first memory block BLK1 as metadata.

During an eighth step \textcircled{8}, the memory device 1200 may move, to a fourth memory block BLK4, the first portion of the data from the first region of the first memory block BLK1 and the second portion of the data from the third region of the third memory block BLK3. For example, the memory device 1200 may move the first portion of the data and the second portion of the data from the third region of the third memory block BLK3 to the fourth memory block BLK4 as a background operation. In some embodiments, the controller 1100 may control the memory device 1200 to move the first portion and the second portion of the data to the fourth memory block BLK4, and the controller 11100 may update the mapping table 1110 with information about the first portion and the second portion of the data moved to the fourth memory block BLK4.

In some embodiments, the memory device 1200 may perform the eighth step \textcircled{8} while performing the sixth step \textcircled{6}. For example, the memory device 1200 may perform the first program operation and the second program operation to write the second memory block BLK2 to the fourth memory block BLK4 before completing the first program operation and the second program operation to the third region of the third memory block BLK3.

The first to eighth steps \textcircled{1} to \textcircled{8} as above are described only to illustrate an embodiment of the present disclosure, however, the embodiments of the present disclosure are not limited thereto.

FIG. 5 is a diagram illustrating first and second program operations. Referring to FIG. 5, the first and second program operations may be performed on a kth memory block BLKk which is an arbitrary memory block of the plurality of memory blocks BLK1 to BLKn of FIGS. 3 and 4, where K is any positive integer. As described above, to write data to a memory block, the memory device 1200 of FIGS. 3 and 4 may perform foggy-fine program operations on the memory block. For example, the memory device 1200 of FIGS. 3 and 4 may perform a first program operation (e.g., a foggy program operation) and a second program operation (e.g., a fine program operation) on the kth memory block BLKk to write the data to the kth memory block BLKk.

The kth memory block may include a plurality of sub-blocks SB1 and SB2. The plurality of sub-blocks SB1 and SB2 may include a plurality of strings ST11 to ST18 and ST21 to ST28, respectively. For better understanding of the present disclosure, each of the plurality of sub-blocks SB1 and SB2 is shown to include eight strings, but the number of strings is not limited thereto. Each of the plurality of sub-blocks SB1 and SB2 may include a different number of strings.

The memory device 1200 of FIGS. 3 and 4 may perform a first program operation and a second program operation on the plurality of strings ST11 to ST18 and ST21 to ST28.

During a first step \textcircled{1}, a first program operation may be performed on a second string ST22 of the second sub-block SB2.

During a second step \textcircled{2}, a second program operation may be performed on the first string ST11 of the first sub-block SB1. The first string ST11 of the first sub-block SB1 may be in a state where the first program operation is completed before the second step \textcircled{2}. After the second program operation is completed on the first string ST11 of the first sub-block SB1, a write operation to the first string ST11 of the first sub-block SB1 may be completed.

During a third step \textcircled{3}, a first program operation may be performed on a third string ST23 of the second sub-block SB2.

During a fourth step \textcircled{4}, a second program operation may be performed on a second string ST12 of the first sub-block SB1. The first string ST11 of the first sub-block SB1 may be in a state where the first program operation is completed before the second step \textcircled{2} or the fourth step \textcircled{4}. After the second program operation on the first string ST11 of the first sub-block SB1 is completed, the write operation on the first string ST11 of the first sub-block SB1 may be completed.

Similarly to the first to fourth operations \textcircled{1} to \textcircled{4}, a first program operation and a second program operation may be performed on the remaining strings of the kth memory block BLKk. When both the first program operation and the second program operation are completed for all strings including the plurality of strings ST11 to ST18 and ST22 to ST28 of the first memory block BLKk, the write operation of the data to the first memory block BLKk may be completed.

The first to fourth steps \textcircled{1} to \textcircled{4} as above are described only to illustrate an embodiment of the present disclosure, however, the embodiments of the present disclosure are not limited thereto. The first program operation and the second program operation for the kth memory block BLKk may be performed in a different order and method than that shown in FIG. 5.

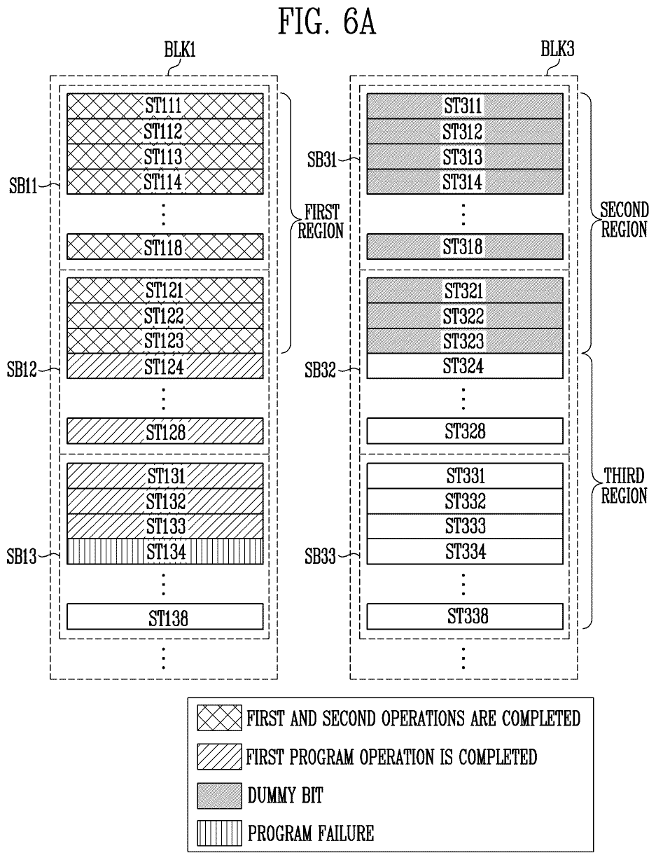

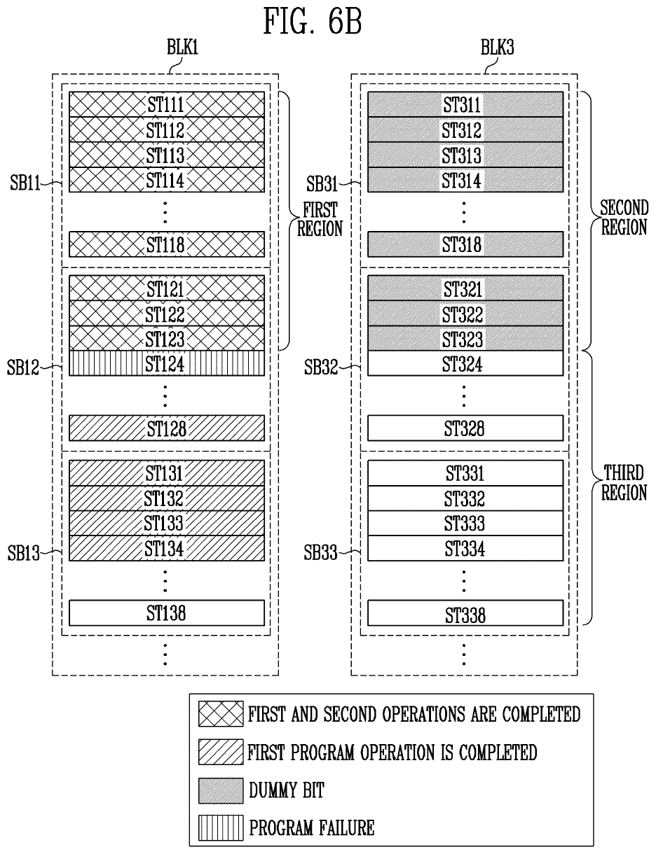

FIG. 6A is a diagram illustrating a copy operation of a memory block according to some embodiments of the present disclosure. Referring to FIG. 6A, the first memory block BLK1 and the third memory block BLK3 may be similar to the first memory block BLK1 and the third memory block BLK3 of FIGS. 3 and 4. The first memory block BLK1 and the third memory block BLK3 may include a plurality of sub-blocks SB11 to SB13 and SB31 to SB33, respectively. For understanding of the present disclosure, each sub-block is shown as including eight strings, but the number of strings is not limited thereto.

A program failure may occur when the memory device 1200 of FIGS. 3 and 4 performs a first program operation and a second program operation on the first memory block BLK1. For example, a program failure may occur while the first program operation for a fourth string ST134 of the third sub-block SB13 of the first memory block BLK1 is performed.

When the program failure occurs, both the first program operation and the second program operation may be completed for the first to eighth strings ST111 to ST118 of the first sub-block SB11 and the first to third strings ST121 to ST123 of the second sub-block SB12, and the first program operation may be completed for the fourth to eighth strings ST124 to ST128 of the second sub-block SB12 and the first to third strings ST131 to ST133 of the third sub-block SB13. The first to eighth strings ST111 to ST118 of the first sub-block SB11 and the first to third strings ST121 to ST123 of the second sub-block SB12 in which both the first program operation and the second program operation are completed may be referred to as a first region.

The memory device 1200 of FIGS. 3 and 4 may perform a first program operation and a second program operation on the third memory block BLK3 to copy or move data to the third memory block BLK3. The memory device 1200 of FIGS. 3 and 4 may write a dummy bit to a second region of the third memory block BLK3 corresponding to the first region of the first memory block BLK1. For example, the memory device 1200 of FIGS. 3 and 4 may write a dummy bit to the first to eighth strings ST311 to ST318 of the first sub-block SB31 of the third memory block BLK3 and the first to third strings ST321 to ST323 of the second sub-block SB32.

The memory device 1200 of FIGS. 3 and 4 may perform a first program operation and a second program operation on a third region which is the remaining region of the third memory block BLK3. For example, the memory device 1200 of FIGS. 3 and 4 may perform the first program operation and the second program operation on the fourth to eighth strings ST324 to ST328 of the second sub-block SB32 of the third memory block BLK3 and the first to eighth strings ST331 to ST338 of the third sub-block SB33 thereof.

While a general memory device requires a large overhead to perform the first program operation and the second program operation on all strings in the third memory block BLK3, the memory device 1200 of FIGS. 3 and 4 may require a small overhead by writing a dummy bit to the second region and performing the first program operation and the second program operation only on the third region which is the remaining region. The memory device 1200 according to an embodiment of the present disclosure may minimize the overhead caused by the program failure by omitting repeated program operations on the data for which the program operation has completed upon the program failure.

FIG. 6B is a diagram illustrating a copy operation of a memory block according to some embodiments of the present disclosure. Referring to FIG. 6B, the first memory block BLK1 and the third memory block BLK3 may be similar to the first memory block BLK1 and the third memory block BLK3 of FIGS. 3 and 4. Each of the first memory block BLK1 and the third memory block BLK3 may include the plurality of sub-blocks SB11 to SB13 and SB31 to SB33. For understanding of the present disclosure, each sub-block is shown as including eight strings, but the number of strings is not limited thereto.

A program failure may occur while the memory device 1200 of FIGS. 3 and 4 performs a first program operation and a second program operation on the first memory block BLK1. For example, a program failure may occur while the second program operation for the fourth string ST124 of the second sub-block SB12 of the first memory block BLK1 is performed.

When the program failure occurs, both the first program operation and the second program operation may be completed for the first to eighth strings ST111 to ST118 of the first sub-block SB11 and the first to third strings ST121 to ST123 of the second sub-block SB12, and the first program operation may be completed for the fourth to eighth strings ST124 to ST128 of the second sub-block SB12 and the first to fourth strings ST131 to ST134 of the third sub-block SB13. The first to eighth strings ST111 to ST118 of the first sub-block SB11 and the first to third strings ST121 to ST123 of the second sub-block SB12 for which both the first program operation and the second program operation are completed may be referred to as a first region.

The memory device 1200 of FIGS. 3 and 4 may perform a first program operation and a second program operation on the third memory block BLK3 to copy or move data to the third memory block BLK3. The memory device 1200 of FIGS. 3 and 4 may write a dummy bit to a second region of the third memory block BLK3 corresponding to the first region of the first memory block BLK1. For example, the memory device 1200 of FIGS. 3 and 4 may write a dummy bit to the first to eighth strings ST311 to ST318 of the first sub-block SB31 of the third memory block BLK3 and the first to third strings ST321 to ST323 of the second sub-block SB32 thereof.

The memory device 1200 of FIGS. 3 and 4 may perform the first program operation and the second program operation on a third region which is the remaining region of the third memory block BLK3. For example, the memory device 1200 of FIGS. 3 and 4 may perform the first program operation and the second program operation on the fourth to eighth strings ST324 to ST328 of the second sub-block SB32 of the third memory block BLK3 and the first to eighth strings ST331 to ST338 of the third sub-block SB33 thereof.

While a general memory device requires a large overhead to perform the first program operation and the second program operation on all strings in the third memory block BLK3, the memory device 1200 of FIGS. 3 and 4 may require a small overhead by writing a dummy bit to the second region and performing the first program operation and the second program operation only on the third region which is the remaining region.

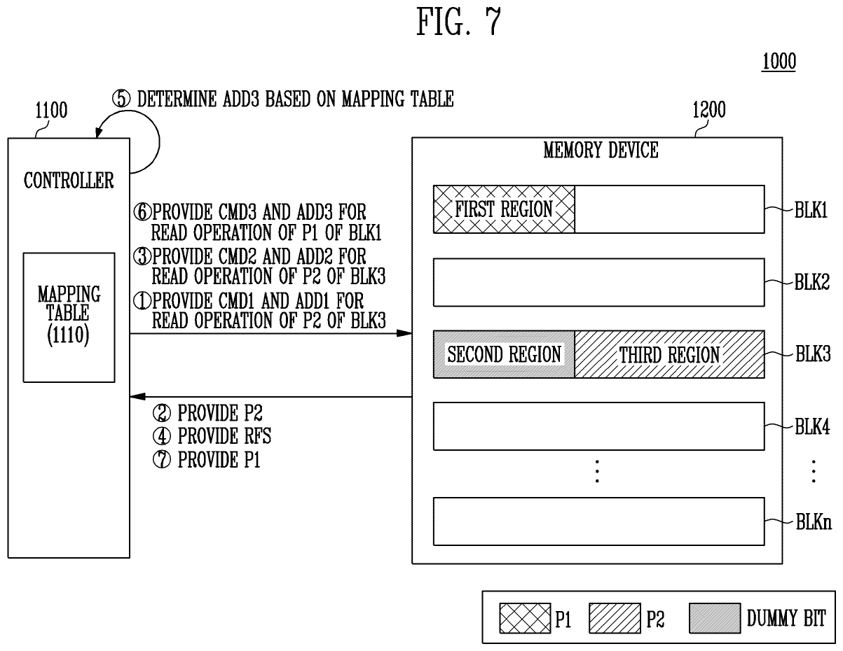

FIG. 7 is a diagram illustrating a read operation of the storage device 1000 according to some embodiments of the present disclosure. Referring to FIG. 7, the storage device 1000 may perform a read operation of data stored within the memory device 1200. The storage device 1000 is similar in some respects to the storage device 1000 of FIGS. 3 and 4, and therefore, a duplicate description thereof will be omitted.

The memory device 1200 may store a first portion P1 of data in a first region of a first memory block, store a dummy bit in a second region of the third memory block BLK3, and store a second portion P2 of the data in a third region of the third memory block BLK3.

The storage device 1000 may perform a read operation of the data stored in the memory device 1200 in response to a read request received from the host device 11 of FIG. 1, and may transfer data to the host device 11 of FIG. 1. For example, the controller 1100 may refer to the mapping table 1110 in response to the read request for the second portion P2 of the data received from the host device 11 of FIG. 1, may determine an address where the data is stored (e.g., a physical address which indicates a physical region within the memory block where the data is stored), and may transfer the data from the region indicated by the address to the host device 11 of FIG. 1.

As described above in FIGS. 3 and 4, the first portion P1 of the data (e.g., the portion of the data for which the first program operation and the second program operation are completed upon the program failure) and the second portion P2 of the data (e.g., the portion of data for which the first program operation and the second program operation have been performed in a replacement memory block after the program failure occurred) may be stored in different memory blocks (e.g., the first memory block BLK1 and the third memory block BLK3). For example, the first portion P1 of the data may be stored in a first region of the first memory block BLK1 and the second portion P2 of the data may be stored in a third region of the third memory block BLK3. A dummy bit may be written to the second region of the third memory block BLK3.

During a first step \textcircled{1}, the controller 1100 may provide the memory device 1200 with a first command CMD1 and a first address ADD1 for a read operation of the second portion P2 of the data. For example, the controller 1100 may refer to the mapping table 1110 in response to a request to read the second portion P2 (or a portion of the second portion P2) of the data received from the host device 11 of FIG. 1, may determine the first address ADD1 based on the mapping table 1110, and may provide the first command CMD1 and the first address ADD1 to the memory device 1200.

During a second step \textcircled{2}, the memory device 1200 may provide the second portion P2 of the data to the controller 1100. For example, based on the received first command CMD1 and the first address ADD1, the memory device 1200 may perform a read operation of the second portion P2 of the data stored in the third region of the third memory block BLK3 indicated by the first address ADD1, and may provide the second portion P2 of the read data to the controller 1100.

During a third step \textcircled{3}, the controller 1100 may provide the memory device 1200 with a second command CMD2 and a second address ADD2 for operating a read operation of the first portion P1 of the data. For example, the controller 1100 may refer to the mapping table 1110 in response to a request to read the first portion P1 (or a portion of the first portion P1) of the data received from the host device 11 of FIG. 1, may determine the second address ADD2 based on the mapping table 1110, and may provide the second command CMD2 and the second address ADD2 to the memory device 1200. The second address ADD2 may indicate a dummy bit stored in a second region of the third memory block BLK3.

During a fourth step \textcircled{4}, the memory device 1200 may provide the read fail signal RFS to the controller 1100. For example, based on the second command CMD2 and the second address ADD2 received from the controller 1100, the memory device 1200 may perform a read operation of the dummy bit stored in the second region of the third memory block BLK3 indicated by the second address ADD2, and may provide the read fail signal RFS to the controller 1100 in response to the read of the dummy bit.

During a fifth step \textcircled{5}, the controller 1100 may determine the third address ADD3 based on the mapping table 1110. For example, the controller 1100 may refer to the mapping table 1110 in response to the read fail signal RFS received from the memory device 1200 and determine the third address ADD3 which indicates a first region of the first memory block BLK1 in which the first portion P1 of the data is stored based on metadata stored in the mapping table 1110.

In some embodiments, the controller 1100 may determine whether a dummy bit is stored in the second region in response to the read fail signal RFS, may refer to the mapping table 1110 in response to determining that the dummy bit is stored in the second region, and may determine the second address ADD2 indicating the second region based on the mapping table 1110.

During a sixth step \textcircled{6}, the controller 1100 may provide the memory device 1200 with a third command CMD3 and a third address ADD3 for a read operation of the first portion P1 of the data. For example, the controller 1100 may determine the third address ADD3 during the fifth step \textcircled{5} and may provide the third command CMD3 and the third address ADD3 to the memory device 1200. The third address ADD3 may indicate the first portion P1 of the data stored in the first region of the first memory block BLK1.

During a seventh step \textcircled{7}, the memory device 1200 may provide the first portion P1 of the data to the controller 1100. For example, based on the received third command CMD3 and third address ADD3, the memory device 1200 may perform a read operation of the first portion P1 of the data stored in the first region of the first memory block BLK1 indicated by the third address ADD3, and may provide the controller 1100 with the first portion P1 of the read data.

The first to seventh steps \textcircled{1} to \textcircled{7} described above are presented to illustrate an embodiment of the present disclosure and are not intended to limit the scope of the present disclosure.

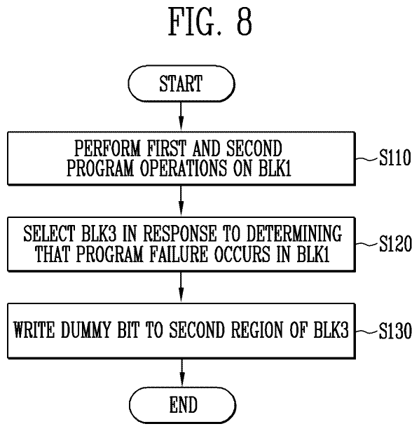

FIG. 8 is a flowchart illustrating a method of operating the storage device 1000 according to an embodiment of the present disclosure. Referring to FIGS. 3 and 8, the storage device 1000 may, upon a program failure, write a dummy bit to a region of a replacement memory block corresponding to a region where a first program operation (e.g., a foggy program operation) and a second program operation (e.g., a fine program operation) have been completed.

At S110, the storage device 1000 or the memory device 1200 may perform a first program operation and a second program operation on the first memory block BLK1. For example, the storage device 1000 or the memory device 1200 may perform the first program operation and the second program operation to copy data from the second memory block BLK2 into the first memory block BLK1. In some embodiments, the memory device 1200 may sequentially perform the first program operation and the second program operation on the plurality of strings in the first memory block BLK1.

At S120, the storage device 1000 or the controller 1100 may select the third memory block in response to determining that a program failure has occurred within the first memory block BLK1. For example, the memory device 1200 may provide a program fail signal to the controller 1100 in response to the program failure occurring while performing the first program operation and the second program operation on the first memory block BLK1, and the controller 1100 may determine that the program failure has occurred within the first memory block BLK1 based on the program fail signal, and may select the third memory block BLK3 from the plurality of memory blocks BLK1 to BLKn as a replacement memory block.

At S130, the storage device 1000 or the memory device 1200 may write a dummy bit to a second region of the third memory block BLK3. The second region of the third memory block BLK3 may correspond to the first region which stores the first portion of the data within the first memory block BLK1 which has completed the first program operation and the second program operation. For example, the controller 1100 may control the memory device 1200 to write the dummy bit to the second region of the third memory block BLK3, and the memory device 1200 may write the dummy bit to the second region of the third memory block BLK3 in response to the control of the controller 1100.

In some embodiments, the controller 1100 may control the memory device 1200 to write the second portion of the data, which is the remaining portion (not the first portion) of the data, to a third region which is the remaining portion (not the second region) of the third memory block BLK3. The controller 1100 may control the memory device 1200 to perform the first program operation and the second program operation to write the second portion of the data to the third region of the third memory block BLK3.

In some embodiments, the storage device 1000 or the controller 1100 may update the mapping table with information about the operations of copying or moving the data to the first memory block BLK1 and the third memory block BLK3, respectively.

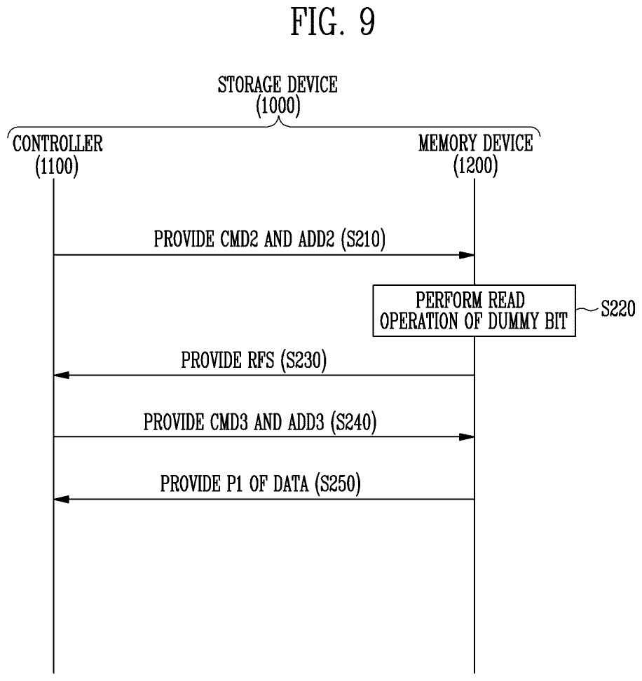

FIG. 9 is a flowchart illustrating a method of operating the storage device 1000 according to some embodiments of the present disclosure. Referring to FIGS. 7 and 9, the storage device 1000 may perform a read operation of data in response to a read request for the data received from the host device 11 of FIG. 1.

At S210, the controller 1100 may provide the second command CMD2 and the second address ADD2 to the memory device 1200. For example, the controller 1100 may refer to the mapping table 1110 based on a read request from the host device 11 of FIG. 1 for the first portion P1 of the data (e.g., a portion of the data for which a first program operation and a second program operation have been completed upon a program failure), and may determine the second address ADD2 based on the mapping table 1110. The second address ADD2 may indicate the third memory block BLK3 where the second portion P2 of the data is stored. The controller 1100 may provide the second command CMD2 and the second address ADD2 to the memory device 1200.

At S220, the memory device 1200 may perform a read operation of a dummy bit. For example, the memory device 1200 may receive the second command CMD2 and the second address ADD2 from the controller 1200 and may read the dummy bit stored in a second region of the third memory block BLK3 indicated by the second address ADD2.

At S230, the memory device 1200 may provide the read fail signal RFS to the controller 1100. For example, the memory device 1200 may read the dummy bit stored in the second region of the third memory block BLK3 indicated by the second address ADD2 and may provide the read fail signal RFS to the controller 1100 in response to reading the dummy bit.

In S240, the controller 1100 may provide the third command CMD3 and the third address ADD3 to the memory device 1200. For example, in response to the read fail signal RFS received from the memory device 1200, the controller 1100 may refer to the mapping table 1110 and determine the third address ADD3 which indicates a first region of the first memory block BLK1 in which the first portion P1 of the data is stored based on metadata in the mapping table 1110. The controller 1100 may provide the memory device 1200 with the third command CMD3 for a read operation of the first portion P1 of the data and the third address ADD3 indicating the first region of the first memory block BLK1.

In some embodiments, the controller 1100 may determine whether a dummy bit is stored in the second region in response to the read fail signal RFS, may refer to the mapping table 1110 in response to determining that the dummy bit is stored in the second region, and may determine the second address ADD2 indicating the second region based on the mapping table 1110.

In some embodiments, though not shown in FIG. 9, when the controller 1100 is unable to determine a physical region where the first portion P1 of the data is stored based on the metadata in the mapping table 1110, the controller 1100 may again provide the memory device 1200 with the second address ADD2 indicating a second region of the third memory block BLK3 and the second command CMD2 for the read operation of the first portion P1 of the data.

At S250, the memory device 1200 may provide the first portion P1 of the data to the controller 1100. For example, the memory device 1200 may perform the read operation of the first portion P1 of the data stored in the first region of the first memory block BLK1 indicated by the third address ADD3 received from the controller 1100 and may provide the first portion P1 of the read data to the controller 1100.

In some embodiments, the memory device 1200 may move the first portion P1 of the data from the first region of the first memory block BLK1 and the second portion P2 of the data from the third region of the third memory block BLK3 to the fourth memory block BLK4 in the background. The memory device 1200 may perform a first program operation and a second program operation on the fourth memory block BLK4 to perform an operation of moving the first portion P1 of the data from the first region of the first memory block BLK1 and the second portion P2 of the data from the third region of the third memory block BLK3.

In some embodiments, upon receiving a read request for the first portion P1 or the second portion P2 of the data from the host device 11 of FIG. 1 before the first program operation and the second program operation for the fourth memory block BLK4 are completed, the controller 1100 may provide a fourth command and a fourth address indicating the first portion P1 stored in the first region or the second portion P2 stored in the third region. The memory device 1200 may perform a read operation of the first portion P1 stored in the first region or the second portion P2 stored in the third region indicated by the fourth address and may provide the read first portion P1 or the read second portion P2 to the controller 1100.

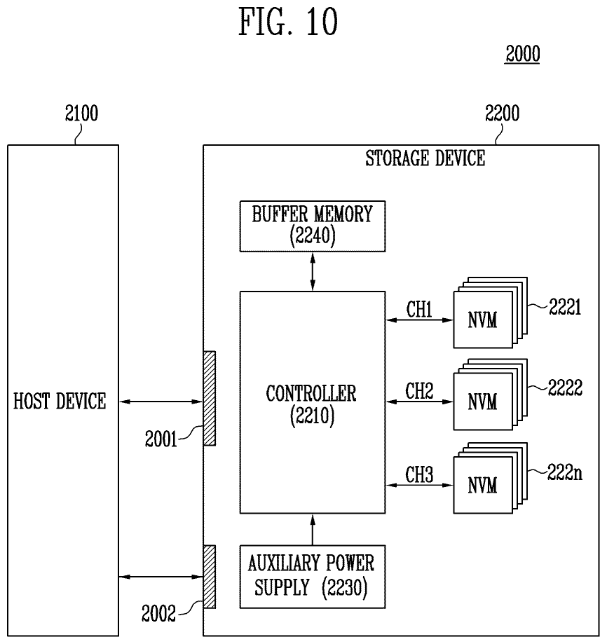

FIG. 10 is a diagram illustrating an electronic system 2000 according to some embodiments of the present disclosure. Referring to FIG. 10, the electronic system 2000 may include a host device 2100 and a storage device 2200. The storage device 2200 may exchange a signal with the host device 2100 through a signal connector 2001 and may receive power through a power connector 2002. The storage device 2200 may include a controller 2210, a plurality of non-volatile memory devices 2221 to 222n, an auxiliary power supply 2230, and a buffer memory 2240.

According to an embodiment, the controller 2210 may perform functions of the controller 1100 of FIGS. 3 and 4.

The controller 2210 may control the plurality of non-volatile memory devices 2221 to 222n in response to signals received from the host device 2100. For example, the signals may be based on an interface between the host device 2100 and the storage device 2200. For example, the signals may be defined by at least one of communication standards or interfaces such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

The auxiliary power supply 2230 may be coupled to the host device 2100 through the power connector 2002. The auxiliary power supply 2230 may receive power input from the host device 2100 and charge the power. When the supply of power from the host device 2100 is not smooth, the auxiliary power supply 2230 may provide power to the storage device 2200. For example, the auxiliary power supply 2230 may be located inside or outside the storage device 2200. For example, the auxiliary power supply 2230 may be located on a main board and provide auxiliary power to the storage device 2200.

The buffer memory 2240 may serve as a buffer memory of the storage device 2200. For example, the buffer memory 2240 may temporarily store data received from the host device 2100 or data received from the plurality of non-volatile memory devices 2221 to 222n, or may temporarily store metadata (e.g., mapping tables) of the non-volatile memory devices 2221 to 222n. The buffer memory 2240 may include volatile memories such as DRAM, SDRAM, DDR SDRAM, and LPDDR SDRAM, or non-volatile memories such as FRAM, ReRAM, STT-MRAM, and PRAM.

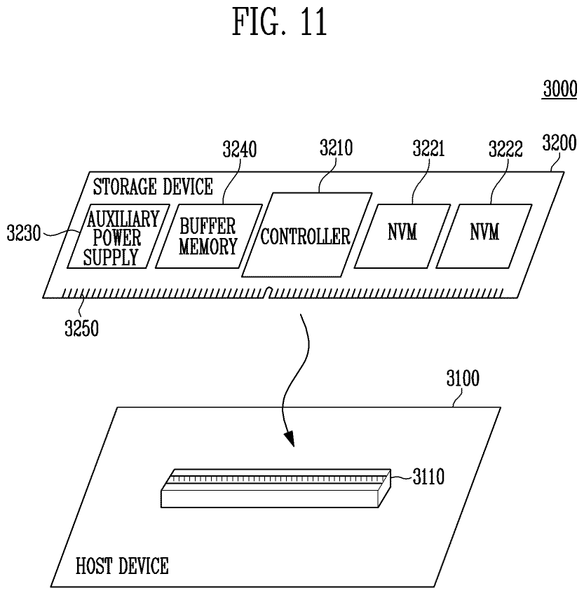

FIG. 11 is a diagram illustrating an electronic system 3000 according to some embodiments of the present disclosure. Referring to FIG. 11, the electronic system 3000 may include a host device 3100 and a storage device 3200.

The host device 3100 may be configured as a board such as a printed circuit board. Though not shown in FIG. 11, the host device 3100 may include internal function blocks for functioning as the host device 3100.

The host device 3100 may include a connection terminal 3110 such as a socket, a slot, or a connector. The storage device 3200 may be mounted onto the connection terminal 3110.

The storage device 3200 may be configured as a board such as a printed circuit board. The storage device 3200 may be referred to as a memory module or a memory card. The storage device 3200 may include a controller 3210, a plurality of non-volatile memories 3231 and 3232, an auxiliary power supply 3230, a buffer memory 3240, and a connection terminal 3250.

The controller 3210 may control the general operations of the storage device 3200. According to an embodiment of the present disclosure, the controller 3210 may perform the functions of the controller 1100 as shown in FIG. 3.

The non-volatile memories 3231 and 3232 may serve as storage media of the storage device 3200.

The auxiliary power supply 3230 may provide power input through the connection terminal 3250 to the background of the storage device 3200. The auxiliary power supply 3230 may manage the power of the storage device 3200, based on the control of the controller 3210.

The buffer memory 3240 may temporarily store data which is to be stored in the non-volatile memories 3231 and 3232. In addition, the buffer memory 3240 may temporarily store data which is read from the non-volatile memories 3231 and 3232. The data which is temporarily stored in the buffer memory 3240 may be transferred to the host device 3100 or the non-volatile memories 3231 and 3232 in response to control of the controller 3210.

The connection terminal 3250 may be coupled to the connection terminal 3110 of the host device 3100. Through the connection terminal 3250, power and signals such as commands, addresses, and data may be transferred between the host device 3100 and the storage device 3200. The connection terminal 3250 may have various configurations depending on an interfacing method of the host device 3100 and the storage device 3200. The connection terminal 3250 may be arranged on one side of the storage device 3200.

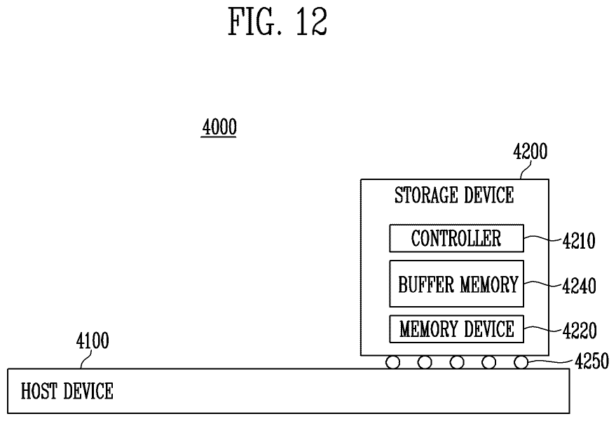

FIG. 12 is a diagram illustrating an electronic system 4000 according to some embodiments of the present disclosure. Referring to FIG. 12, the electronic system 4000 may include a host device 4100 and a storage device 4200.

The host device 4100 may be configured as a board such as a printed circuit board. Though not shown in FIG. 14, the host device 4100 may include background function blocks for performing functions of the host device 4100.

The storage device 4200 may be configured as a surface mount package type. The storage device 4200 may be mounted onto the host device 4100 through a solder ball 4250. The storage device 4200 may include a controller 4210, a memory device 4220, and a buffer memory 4240.

The controller 4210 may control the general operations of the storage device 4200. According to an embodiment of the present disclosure, the controller 4210 may perform the functions of the controller 1100 as shown in FIG. 3.

The buffer memory 4240 may temporarily store data which is to be stored in the memory device 4240. In addition, the buffer memory 4240 may temporarily store data read from non-volatile memory devices 4230. The data which is temporarily stored in the buffer memory 4240 may be transferred to the host device 4100 or the memory device 4220 in response to control of the controller 4210.

The memory device 4220 may serve as a storage medium of the storage device 4200.

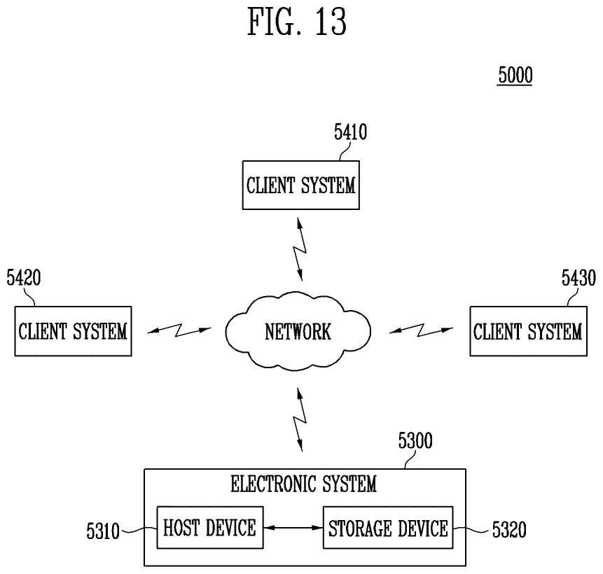

FIG. 13 is a diagram illustrating a network system 5000 including an electronic system according to some embodiments of the present disclosure. Referring to FIG. 13, the network system 5000 may include an electronic system 5300 and a plurality of client systems 5410 to 5430 through a network 5500.

The electronic system 5300 may provide data services in response to a request from the plurality of client systems 5410 to 5430. For example, the electronic system 5300 may store data provided from the plurality of client systems 5410 to 5430. In another embodiment, the electronic system 5300 may provide data to the plurality of client systems 5410 to 5430.

The electronic system 5300 may include a host device 5310 and a storage device 5320. The host device 5310 may be configured using the host device 11 of FIG. 1, and the storage device 5320 may be configured using the storage device 1000 of FIG. 1.

According to embodiments of the present disclosure, a storage device performing program operations on memory blocks, a method of operating the storage device, and a method of operating an electronic system including the storage device may be provided.

In addition, according to embodiments of the present disclosure, a storage device, a method of operating the storage device, and a method of operating an electronic system including the storage device that reduce an overhead caused by a program failure by omitting repeated program operations for data for which a program operation is completed at the time of a program failure may be provided.

It will be apparent to those skilled in the art that various modifications can be made to the above-described embodiments of the present disclosure without departing from the spirit or scope of the present disclosure. Thus, it is intended that the embodiments include all such modifications provided they fall within the scope of the appended claims and their equivalents. Furthermore, the embodiments may be combined to form additional embodiments.

What is claimed is:

1. A storage device comprising:
a memory device including a plurality of memory blocks, and configured to perform a first program operation and a second program operation on a first memory block among the plurality of memory blocks to copy data from a second memory block into the first memory block; and
a controller configured to control the memory device to select a third memory block among the plurality of memory blocks in response to a program failure that occurs in the first memory block and to write a dummy bit to a second region of the third memory block corresponding to a first region of the first memory block,
wherein the first region stores a first portion of the data for which the first program operation and the second program operation are completed.

2. The storage device of claim 1, wherein the memory device is configured to perform the first program operation and the second program operation to copy a second portion other than the first portion within the data from the second memory block to a third region of the third memory block.

3. The storage device of claim 2, wherein the controller is further configured to control the memory device to select a fourth memory block from the plurality of memory blocks and to copy, into the fourth memory block, the first portion from the first region and the second portion from the third region.

4. The storage device of claim 3, wherein the memory device is further configured to perform the first program operation and the second program operation on the fourth memory block for copying the first portion and the second portion into the fourth memory block, and
wherein the controller is further configured to provide the memory device with a first command and a first address for a read operation of the first portion stored in the first region or a read operation of the second portion stored in the third region in response to receiving a read request for the data from an external host device prior to completion of the first program operation and the second program operation on the fourth memory block.

5. The storage device of claim 1, wherein the memory device is configured to:
perform the first program operation on a first string of the first memory block,
perform the second program operation on a second string of the first memory block, wherein the second string is adjacent to the first string and the first program operation is completed on the second string, and
provide a program fail signal to the controller in response to the program failure occurring in at least one of the first string and the second string.

6. The storage device of claim 1, wherein the controller comprises a mapping table and is configured to update the mapping table with information about operations of copying the data from the second memory block respectively to the first memory block and the third memory block.

7. The storage device of claim 1, wherein the controller is configured to provide the memory device with a first command for a read operation of the first portion and a first address indicating the second region, and provide the memory device with a second command for the read operation of the first portion and a second address indicating the first region in response to a read fail signal received from the memory device, and
wherein the memory device is configured to read the dummy bit of the second region indicated by the first address in response to the first command, provide the read fail signal to the controller in response to reading the dummy bit, and provide the controller with the first portion stored in the first region indicated by the second address based on the second command.

8. The storage device of claim 7, wherein the controller comprises a mapping table, and is configured to refer to the mapping table in response to the read fail signal and determine the second address based on the mapping table.

9. The storage device of claim 7, wherein the controller is configured to determine whether the dummy bit is stored in the second region in response to the read fail signal, and determine the second address in response to determining that the dummy bit is stored in the second region.

10. The storage device of claim 1, wherein the memory device is configured to perform at least one of a garbage collection operation, a read reclaim operation, a read refresh operation, a wear leveling operation, and an over-provision operation.

11. The storage device of claim 1, wherein the plurality of memory blocks comprises memory cells including at least one of a single level cell (SLC), a multi-level cell (MLC), a triple level cell (TLC), and a quadruple level cell (QLC).

12. A method of operating a storage device including a controller and a memory device, the method comprising:
performing, by the memory device, a first program operation and a second program operation on a first memory block to copy data from a second memory block into the first memory block;
selecting, by the controller, a third memory block in response to a program failure that occurs in the first memory block; and
writing, by the memory device, a dummy bit to a second region of the third memory block corresponding to a first region of the first memory block,
wherein the first region stores a first portion of the data for which the first program operation and the second program operation are completed.

13. The method of claim 12, further comprising performing, by the memory device, the first program operation and the second program operation on a third region of the third memory block to copy a second portion other than the first portion within the data from the second memory block to the third region.

14. The method of claim 13, further comprising copying, by the memory device, the first portion from the first region and the second portion from the third region into a fourth memory block.

15. The method of claim 14, further comprising:
performing, by the memory device, the first program operation and the second program operation on the fourth memory block to copy the first portion and the second portion into the fourth memory block;
receiving, by the controller, a read request for the data from an external host device prior to completion of the first program operation and the second program operation on the fourth memory block; and
providing, by the controller, a first command and a first address for a read operation of the first portion stored in the first region or the second portion stored in the third region to the memory device in response to the read request.

16. The method of claim 12, further comprising updating, by the controller, a mapping table with information about operations of copying the data from the second memory block respectively into the first memory block and the third memory block.

17. The method of claim 12, further comprising:
providing, by the controller, the memory device with a first command for a read operation of the first portion and a first address indicating the second region;
reading, by the memory device, the dummy bit of the second region indicated by the first address in response to the first command;
providing, by the memory device, a read fail signal to the controller based on reading the dummy bit;
providing, by the controller, the memory device with a second command for the read operation of the first portion and a second address indicating the first region in response to the read fail signal; and
providing, by the memory device, the first portion stored in the first region indicated by the second address to the controller, based on the second command.

18. The method of claim 17, wherein providing the memory device with the second command and the second address comprises:
referring to, by the controller, a mapping table in response to the read fail signal;
determining, by the controller, the second address based on the mapping table; and
providing, by the controller, the memory device with the second command for the read operation of the first portion and the second address indicating the first region in response to the read fail signal.

19. The method of claim 17, wherein providing the memory device with the second command and the second address comprises:
determining, by the controller, whether the dummy bit is stored in the second region in response to the read fail signal;
determining the second address in response to determining that the dummy bit is stored in the second region; and
providing, by the controller, the memory device with the second command and a second address indicating the first region.

20. A method of operating an electronic system including a host device, a controller and a memory device, the method comprising:
performing, by the memory device, a first program operation and a second program operation on a first memory block to copy data from a second memory block into the first memory block;
selecting, by the controller, a third memory block in response to a program failure that occurs in the first memory block;
writing, by the memory device, a dummy bit to a second region of the third memory block corresponding to a first region of the first memory block, wherein the first region stores a first portion of the data for which the first program operation and the second program operation are completed;
transferring, by the host device, a read request for the first portion to the controller;
providing, by the controller, the memory device with a first command for a read operation of the first portion and a first address indicating the second region in response to the read request;
reading, by the memory device, the dummy bit from the second region indicated by the first address in response to the first command;
providing, by the memory device, a read fail signal to the controller based on reading the dummy bit;
providing, by the controller, the memory device with a second command for the read operation of the first portion and a second address indicating the first region in response to the read fail signal;
providing, by the memory device, the first portion stored in the first region indicated by the second address to the controller based on the second command; and
transferring, by the controller, the first portion to the host device.
